(19) United States
(12) Patent Application Publication
(10) Pub. No.: US 2020/0117091 A1
(43) Pub. Date: Apr. 16, 2020

(54) PATTERN-FORMING METHOD, AND SILICON-CONTAINING FILM-FORMING COMPOSITION

(71) Applicant: JSR CORPORATION, Tokyo (JP)

(72) Inventors: Tomoaki SEKO, Tokyo (JP); Tomoya TAJI, Tokyo (JP); Nozomi SATOU, Tokyo (JP); Tetsuya SAKAI, Tokyo (JP)

(73) Assignee: JSR CORPORATION, Tokyo (JP)

(21) Appl. No.: 16/711,916

(22) Filed: Dec. 12, 2019

Related U.S. Application Data
(63) Continuation of application No. PCT/JP2018/022817, filed on Jun. 14, 2018.

(30) Foreign Application Priority Data
Jun. 16, 2017 (JP) 2017-119027

(51) Int. Cl. G03F 7/11; C09D 183/04

(52) U.S. Cl. CPC G03F 7/11; G03F 7/16; C09D 183/04

(57) ABSTRACT

The pattern-forming method includes: applying a silicon-containing film-forming composition directly or indirectly on at least an upper face side of a substrate to form a silicon-containing film; applying a resist film-forming composition directly or indirectly on an upper face side of the silicon-containing film to form a resist film; exposing the resist film to an extreme ultraviolet ray or an electron beam; and developing the resist film exposed to form a resist pattern. The silicon-containing film-forming composition contains a compound having a first structural unit represented by formula (1), and a solvent. In the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

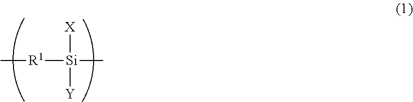

### CROSS-REFERENCE TO RELATED APPLICATIONS

The present application is a continuation application of International Application No. PCT/JP2018/022817, filed Jun. 14, 2018, which claims priority to Japanese Patent Application No. 2017-119027, filed Jun. 16, 2017. The contents of these applications are incorporated herein by reference in their entirety.

### BACKGROUND OF THE INVENTION

### Field of the Invention

The present invention relates to a pattern-forming method and a silicon-containing film-forming composition.

### Discussion of the Background

In pattern formation of semiconductor elements and the like, a resist process is frequently employed which includes: exposing and developing a resist film laminated via an organic antireflective film and a silicon-containing film provided on a substrate to be processed; and using the resist pattern thus obtained as a mask to permit etching. Along with microfabrication of resist patterns in recent years, it has become necessary to improve etching selectivity of mask patterns. In this respect, for the purpose of improving the etching selectivity of the mask patterns, investigations have been made on silicon-containing film-forming compositions and methods for forming a pattern on a substrate using such a silicon-containing film-forming composition (see Japanese Unexamined Patent Application, Publication No. 2004-310019 and PCT International Publication No. 2012/039337).

Recently, enhanced integration of semiconductor devices has been progressing further, and the wavelength of the exposure light to be used tends to be shortened from a KrF excimer laser beam (248 nm) or an ArF excimer laser beam (193 nm) to an extreme ultraviolet ray (13.5 nm; hereinafter, may be also referred to as “EUV”).

However, under current circumstances in which microfabrication of resist patterns has been enhanced to have a line width of no greater than 20 nm as formed by exposure to an extreme ultraviolet ray, followed by development, a silicon-containing film has been desired that is superior in a resist pattern collapse-inhibiting property as well as resistance to a solvent of a resist composition. In addition, with respect to the film thickness of silicon-containing films, thinner films have been extensively provided to have the thickness of no greater than 10 nm, whereby the demanded level for etching selectivity has been further elevated.

### SUMMARY OF THE INVENTION

According to an aspect of the present invention, a pattern-forming method includes: applying a silicon-containing film-forming composition directly or indirectly on at least an upper face side of a substrate to form a silicon-containing film; applying a resist film-forming composition directly or indirectly on an upper face side of the silicon-containing film to form a resist film; exposing the resist film to an extreme ultraviolet ray or an electron beam; and developing the resist film exposed to form a resist pattern. The silicon-containing film-forming composition contains a compound having a first structural unit represented by formula (1), and a solvent. In the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

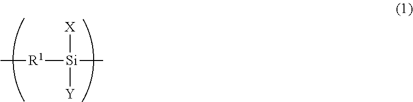

According to another aspect of the present invention, a silicon-containing film-forming composition includes a compound comprising a structural unit represented by formula (1), and a solvent. In the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

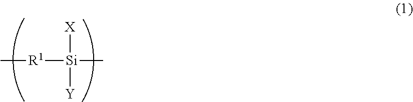

### DESCRIPTION OF THE EMBODIMENTS

According to an embodiment of the invention, a pattern-forming method includes: applying a silicon-containing film-forming composition directly or indirectly on at least an upper face side of a substrate; applying a resist film-forming composition directly or indirectly on an upper face side of a silicon-containing film formed by applying the silicon-containing film-forming composition; exposing to an extreme ultraviolet ray (EUV) or an electron beam, a resist film formed by applying the resist film-forming composition; and developing the resist film exposed, wherein the silicon-containing film-forming composition comprises: a compound (hereinafter, may be also referred to as “(A) compound” or “compound (A)”) comprising a first structural unit (hereinafter, may be also referred to as “structural unit (I)”) represented by formula (1); and a solvent (hereinafter, may be also referred to as “(B) solvent” or “solvent (B)”).

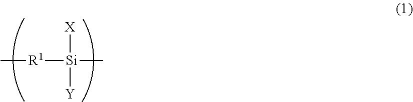

In the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

According to another embodiment of the present invention made for solving the aforementioned problems, a silicon-containing film-forming composition for EUV lithography comprises: a compound having a structural unit represented by the following formula (1); and a solvent.

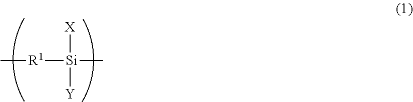

In the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

The pattern-forming method and the silicon-containing film-forming composition for EUV lithography according to the embodiments of the present invention enable a silicon-containing film to be formed with a superior resist pattern collapse-inhibiting property and superior resistance to etching by oxygen-based gas and to solvents. Therefore, these can be suitably used for the manufacture, etc., of semiconductor devices, for which further progress of miniaturization is expected in the future.

Hereinafter, a pattern-forming method and a silicon-containing film-forming composition for EUV lithography according to embodiments of the present invention will be described in detail.

### Pattern-Forming Method

The pattern-forming method includes the steps of: applying a silicon-containing film-forming composition for EUV lithography (hereinafter, may be also referred to simply as “silicon-containing film-forming composition”) directly or indirectly on at least an upper face side of a substrate (hereinafter, may be also referred to as “silicon-containing film-forming composition-applying step”); applying a resist film-forming composition directly or indirectly on an upper face side of a silicon-containing film formed by applying the silicon-containing film-forming composition (hereinafter, may be also referred to as “resist film-forming composition-applying step”); exposing to an extreme ultraviolet ray (EUV) or an electron beam, a resist film formed by applying the resist film-forming composition (hereinafter, may be also referred to as “exposing step”); and developing the resist film exposed (hereinafter, may be also referred to as “developing step”), wherein the silicon-containing film-forming composition contains the compound (A) and the solvent (B) described later.

The pattern-forming method enables a silicon-containing film to be formed with a superior resist pattern collapse-inhibiting property, superior resistance to etching by oxygen-based gas and to solvents since the silicon-containing film-forming composition is used in the silicon-containing film-forming composition-applying step.

The pattern-forming method may include other step(s) as needed. The pattern-forming method may include, after the developing step, the steps of: etching the silicon-containing film using, as a mask, a resist pattern formed by the developing step (hereinafter, may be also referred to as “silicon-containing film-etching step”); etching the substrate using, as a mask, the silicon-containing film etched (hereinafter, may be also referred to as “substrate-etching step”); and removing the silicon-containing film (hereinafter, may be also referred to as “silicon-containing film-removing step”). Also, the pattern-forming method may include before the silicon-containing film-forming composition-applying step, a step of forming an organic underlayer film directly or indirectly on at least an upper face side of the substrate (hereinafter, may be also referred to as “organic underlayer film-forming step”), and may include, after the silicon-containing film-etching step, etching the organic underlayer film using, as a mask, the silicon-containing film etched (hereinafter, may be also referred to as “organic underlayer film-etching step”).

Organic Underlayer Film-Forming Step

In this step, an organic underlayer film is formed directly or indirectly on at least an upper face side of a substrate.

In the pattern-forming method of the embodiment of the present invention, the silicon-containing film-forming composition-applying step described later may be carried out after the organic underlayer film-forming step, in a case in which the organic underlayer film-forming step is carried out. In this case, the silicon-containing film is formed by applying the silicon-containing film-forming composition on the organic underlayer film, in the silicon-containing film-forming composition-applying step.

Examples of the substrate include insulating films of silicon oxide, silicon nitride, silicon nitride oxide, polysiloxane, etc., as well as resin substrates and the like. For example, an interlayer insulating film of, e.g., a wafer coated with a low-dielectric insulating film formed from “Black Diamond” available from AMAT, “SiLK” available from Dow Chemical, “LKD5109” available from JSR Corporation or the like may be used. A substrate patterned so as to have wiring grooves (trenches), plug grooves (vias) or the like may also be used as the substrate.

The organic underlayer film is different from the silicon-containing film formed from the silicon-containing film-forming composition. However, the organic underlayer film may contain a silicon atom. The organic underlayer film serves in further compensating for a function exhibited by the silicon-containing film and/or the resist film in resist pattern formation, as well as in imparting a necessary specific function for attaining a function not exhibited by the silicon-containing film and/or the resist film (for example, an antireflective property, coating film flatness, or high etching resistance to fluorine-based gas).

The organic underlayer film is exemplified by an antireflective film and the like. An exemplary antireflective silicon-containing film-forming composition may include “NFC HM8006” available from JSR Corporation and the like.

The organic underlayer film may be formed by applying an organic-underlayer film-forming composition through spin coating or the like to form a coating film, followed by heating.

Silicon-Containing Film-Forming Composition-Applying Step

In this step, the silicon-containing film-forming composition for EUV lithography of the embodiment of the present invention described later is applied. By this step, a coating film of the silicon-containing film-forming composition is formed on the substrate directly or via another layer such as the organic underlayer film. A procedure for applying the silicon-containing film-forming composition is not particularly limited, and a known method such as, e.g., spin coating may be exemplified.

The silicon-containing film is generally formed by exposure and/or heating, thereby allowing, for example, hardening of the coating film provided by directly or indirectly applying the silicon-containing film-forming composition on the substrate.

Examples of the radioactive ray used for the exposure include electromagnetic waves such as a visible light ray, an ultraviolet ray, a far ultraviolet ray, an X-ray and a γ-ray; particle rays such as an electron beam, a molecular beam and an ion beam; and the like.

The lower limit of the temperature in heating the coating film is preferably 90° C., more preferably 150° C., and still more preferably 200° C. The upper limit of the temperature is preferably 550° C., more preferably 450° C., and still more preferably 300° C. The lower limit of the average thickness of the silicon-containing film formed is preferably 1 nm, more preferably 3 nm, and still more preferably 5 nm. The upper limit of the average thickness is preferably 100 nm, more preferably 50 nm, and still more preferably 30 nm.

### Silicon-Containing Film-Forming Composition for EUV Lithography

The silicon-containing film-forming composition for EUV lithography of the embodiment of the present invention contains the compound (A) and the solvent (B). The silicon-containing film-forming composition may contain other optional component(s) within a range not leading to impairment of the effects of the present invention. The silicon-containing film-forming composition may be suitably used for EUV lithography.

### (A) Compound

The compound (A) has the structural unit (I). The compound (A) may further have a second structural unit (hereinafter, may be also referred to as “structural unit (II)”) and a third structural unit (hereinafter, may be also referred to as “structural unit (III)”), described later, as arbitrary structural units. In the silicon-containing film-forming composition, the compound (A) may be used either alone as one type, or in a combination of two or more types thereof.

Structural Unit (I)

The structural unit (I) is represented by the following formula (1).

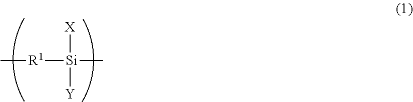

In the above formula (1), R¹ represents a substituted or unsubstituted divalent hydrocarbon group having 1 to 20 carbon atoms; and X and Y each represent a hydrogen atom, a hydroxy group, a halogen atom or a monovalent organic group having 1 to 20 carbon atoms.

By virtue of the compound (A) having the structural unit (I), the silicon-containing film-forming composition enables formation of the silicon-containing film, which is superior in the resist pattern collapse-inhibiting property, resistance to etching by oxygen-based gas, and solvent resistance. Although not necessarily clarified and without wishing to be bound by any theory, the reason for achieving the effects described above by the silicon-containing film-forming composition may be supposed as in the following, for example. Due to the silicon-containing film-forming composition having a carbosilane skeleton derived from the structural unit (I) described above, the silicon-containing film would be superior in solvent resistance. In addition, due to the aforementioned carbosilane skeleton included, it is speculated that permeability of a developer solution at the interface of the silicon-containing film and the resist film is appropriately controlled, thereby leading to improved resist pattern formability and enabling a silicon-containing film to be formed that achieves a resist pattern collapse-inhibiting property. Furthermore, it is envisaged that due to the carbosilane skeleton being less polarized therein, the silicon-containing film-forming composition is less likely to be attacked by a substance used for etching the silicon-containing film, thereby enabling formation of a silicon-containing film that is superior in resistance to etching by oxygen-based gas.

R¹ in the above formula (1) is exemplified by a substituted or unsubstituted divalent chain hydrocarbon group having 1 to 20 carbon atoms, a substituted or unsubstituted divalent cycloaliphatic hydrocarbon group having 3 to 20 carbon atoms, and a substituted or unsubstituted divalent aromatic hydrocarbon group having 6 to 20 carbon atoms. It is to be noted that as referred to herein, the chain hydrocarbon group involves both a linear hydrocarbon group and a branched chain hydrocarbon group.

Examples of the unsubstituted divalent chain hydrocarbon group having 1 to 20 carbon atoms include: chain saturated hydrocarbon groups such as a methanediyl group and an ethanediyl group; chain unsaturated hydrocarbon groups such as an ethenediyl group and a propenediyl group; and the like.

Examples of the unsubstituted divalent cycloaliphatic hydrocarbon group having 3 to 20 carbon atoms include: monocyclic saturated hydrocarbon groups such as a cyclobutanediyl group; monocyclic unsaturated hydrocarbon groups such as a cyclobutenediyl group; polycyclic saturated hydrocarbon groups such as a bicyclo[2.2.1]heptanediyl group; polycyclic unsaturated hydrocarbon groups such as a bicyclo[2.2.1]heptenediyl group; and the like.

Examples of the unsubstituted divalent aromatic hydrocarbon group having 6 to 20 carbon atoms include a phenylene group, a biphenylene group, a phenyleneethylene group, a naphthylene group, and the like.

Examples of the substituent in the substituted divalent hydrocarbon group having 1 to 20 carbon atoms represented by R′ include a halogen atom, a hydroxy group, a cyano group, a nitro group, an alkoxy group, an acyl group, an acyloxy group, and the like.

R¹ represents preferably the unsubstituted chain saturated hydrocarbon group, and more preferably a methanediyl group or an ethanediyl group.

The monovalent organic group which may be represented by X or Y in the above formula (1) is exemplified by: a monovalent hydrocarbon group having 1 to 20 carbon atoms; a monovalent group (a) obtained from the monovalent hydrocarbon group by incorporating a divalent hetero atom-containing group between two adjacent carbon atoms thereof; a monovalent group 03) obtained by substituting with a monovalent hetero atom-containing group a part or all of the hydrogen atoms included in the monovalent hydrocarbon group or the group (a) including the divalent hetero atom-containing group; and the like.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group and an ethyl group; alkenyl groups such as an ethenyl group; alkynyl groups such as an ethynyl group; and the like.

Examples of the monovalent alicyclic hydrocarbon group having 3 to 20 carbon atoms include: monovalent monocyclic alicyclic saturated hydrocarbon groups such as a cyclopentyl group and a cyclohexyl group; monovalent monocyclic alicyclic unsaturated hydrocarbon groups such as a cyclopentenyl group and a cyclohexenyl group; monovalent polycyclic alicyclic saturated hydrocarbon groups such as a norbornyl group and an adamantyl group; monovalent polycyclic alicyclic unsaturated hydrocarbon groups such as a norbornenyl group and a tricyclodecenyl group; and the like.

Examples of the monovalent aromatic hydrocarbon group having 6 to 20 carbon atoms include: aryl groups such as a phenyl group, a tolyl group, a xylyl group, a naphthyl group, a methylnaphthyl group and an anthryl group; aralkyl groups such as a benzyl group, a naphthylmethyl group and an anthryl methyl group; and the like.

The hetero atom constituting the divalent or monovalent hetero atom-containing group is exemplified by an oxygen atom, a nitrogen atom, a sulfur atom, a phosphorus atom, a silicon atom, a halogen atom, and the like. Examples of the halogen atom include a fluorine atom, a chlorine atom, a bromine atom, an iodine atom, and the like.

Examples of the divalent hetero atom-containing group include —O—, —CO—, —S—, —CS—, —NR′—, groups obtained by combining at least two of the aforementioned groups, and the like, wherein R′ represents a hydrogen atom or a monovalent hydrocarbon group.

Examples of the monovalent hetero atom-containing group include halogen atoms such as a fluorine atom, a chlorine atom, a bromine atom and an iodine atom, a hydroxy group, a carboxy group, a cyano group, an amino group, a sulfanyl group, and the like.

The monovalent organic group which may be represented by X or Y is preferably the monovalent hydrocarbon group, more preferably the monovalent chain hydrocarbon group or the monovalent aromatic hydrocarbon group, and still more preferably the alkyl group or the aryl group.

The number of carbon atoms of the monovalent organic group which may be represented by X or Y is preferably no less than 1 and no greater than 10, and more preferably no less than 1 and no greater than 6.

Examples of the halogen atom which may be represented by X or Y include a fluorine atom, a chlorine atom, a bromine atom, an iodine atom, and the like. The halogen atom is preferably a chlorine atom or a bromine atom.

The lower limit of the proportion of the structural unit (I) contained with respect to the total structural units constituting the compound (A) is preferably 5 mol %, more preferably 30 mol %, still more preferably 60 mol %, and particularly preferably 80 mol %. Meanwhile, the upper limit of the proportion of the structural unit (I) contained is not particularly limited, and may be 100 mol %. When the proportion of the structural unit (I) contained falls within the above range, the resist pattern collapse-inhibiting property, resistance to etching by oxygen-based gas and solvent resistance of the silicon-containing film formed from the silicon-containing film-forming composition can be further improved.

Structural Unit (II)

The structural unit (II) is an arbitrary structural unit which may be included in the compound (A) and is represented by the following formula (2).

(SiO_{4/2}) (2)

In the case in which the compound (A) has the structural unit (II), the lower limit of the proportion of the structural unit (II) contained with respect to the total structural units constituting the compound (A) is preferably 0.1 mol %, more preferably 1 mol %, and still more preferably 5 mol %. Meanwhile, the upper limit of the proportion of the structural unit (II) contained is preferably 50 mol %, more preferably 40 mol %, still more preferably 30 mol %, and particularly preferably 20 mol %.

Structural Unit (III)

The structural unit (III) is an arbitrary structural unit which may be included in the compound (A) and is represented by the following formula (3).

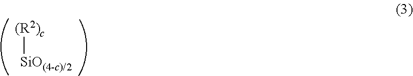

In the above formula (3), R² represents a substituted or unsubstituted monovalent hydrocarbon group having 1 to 20 carbon atoms; and c is an integer of 1 or 2, wherein in a case in which c is 2, two R²s are identical or different.

It is preferred that c is 1.

Examples of R² include groups similar to the monovalent hydrocarbon groups having 1 to 20 carbon atoms exemplified for X and Y in the above formula (1), and the like. Moreover, examples of the substituent for the monovalent hydrocarbon group having 1 to 20 carbon atoms include groups similar to the monovalent hetero atom-containing groups exemplified for X and Y in the above formula (1), and the like.

R² represents preferably the substituted or unsubstituted monovalent chain hydrocarbon group or the substituted or unsubstituted monovalent aromatic hydrocarbon group, more preferably the alkyl group or the aryl group, and still more preferably a methyl group or a phenyl group.

In a case in which the compound (A) has the structural unit (III), the lower limit of the proportion of the structural unit (III) contained with respect to the total structural units constituting the compound (A) is preferably 0.1 mol %, more preferably 1 mol %, and still more preferably 5 mol %. The upper limit of the proportion of the structural unit (III) contained is preferably 50 mol %, more preferably 40 mol %, still more preferably 30 mol %, and particularly preferably 20 mol %.

Furthermore, in addition to the structural units described above, the compound (A) may include a structural unit having a structure of Si—O—Si formed by dehydrative condensation or the like from the hydroxy group represented by X and/or Y in the above formula (1).

### (B) Solvent

The silicon-containing film-forming composition contains the solvent (B). The solvent (B) is exemplified by an alcohol solvent, a ketone solvent, an ether solvent, an ester solvent, a nitrogen-containing solvent, water, and the like. The solvent (B) may be used either alone as one type, or in a combination of two or more types thereof.

Examples of the alcohol solvent include: monohydric alcohol solvents such as methanol, ethanol, n-propanol, iso-propanol, n-butanol and iso-butanol; polyhydric alcohol solvents such as ethylene glycol, 1,2-propylene glycol, diethylene glycol and dipropylene glycol; and the like.

Examples of the ketone solvent include acetone, methyl ethyl ketone, methyl n-propyl ketone, methyl iso-butyl ketone, cyclohexanone, and the like.

Examples of the ether solvent include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvent include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate, and the like.

Examples of the nitrogen-containing solvent include N,N-dimethylformamide, N,N-dimethylacetamide, N-methylpyrrolidone, and the like.

Of these, the ether solvent and/or the ester solvent are/is preferred, and since superior film formability can be provided, the ether solvent and/or the ester solvent each having a glycol structure are/is more preferred.

Examples of the ether solvent and the ester solvent each having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like. Of these, in particular, propylene glycol monomethyl ether acetate is preferred.

The lower limit of the percentage content of the ether solvent and the ester solvent each having the glycol structure in the solvent (B) is preferably 20% by mass, more preferably 60% by mass, still more preferably 90% by mass, and particularly preferably 100% by mass.

The lower limit of the content of the solvent (B) in the silicon-containing film-forming composition is preferably 80% by mass, more preferably 90% by mass, and still more preferably 95% by mass. The upper limit of the content is preferably 99.9% by mass.

Optional Components

The silicon-containing film-forming composition may further contain as optional components, for example, a basic compound (including a base generating agent), a radical generating agent, an acid generating agent, a surfactant, colloidal silica, colloidal alumina, an organic polymer and the like. These optional components may each be used either alone as one type, or in a combination of two or more types thereof.

Basic Compound

The basic compound promotes a hardening reaction of the silicon-containing film-forming composition, and consequently, properties such as the strength of the silicon-containing film formed can be improved. In addition, the basic compound improves peelability of the silicon-containing film by an acidic liquid. The basic compound is exemplified by a compound having a basic amino group, and a base generating agent or the like that is capable of generating a compound having a basic amino group by an action of an acid or an action of heat. Exemplary compounds having the basic amino groups include amine compounds and the like. Exemplary base generating agents include an amide group-containing compound, a urea compound, a nitrogen-containing heterocyclic compound, and the like. Specific examples of the amine compound, the amide group-containing compound, the urea compound and the nitrogen-containing heterocyclic compound include, for example, compounds disclosed in paragraphs [0079] to [0082] of Japanese Unexamined Patent Application, Publication No. 2016-27370.

In the case in which the silicon-containing film-forming composition contains the basic compound, the content of the basic compound with respect to 100 parts by mass of the compound (A) is, for example, no less than 1 part by mass and no greater than 50 parts by mass.

Acid Generating Agent

The acid generating agent is a component that is capable of generating an acid upon exposure or heating. When the silicon-containing film-forming composition contains the acid generating agent, promotion of the condensation reaction of the compound (A) is enabled even at a comparatively low temperature (including a normal temperature).

Examples of the acid generating agent that is capable of generating an acid upon exposure (hereinafter, may be also referred to as “photo acid generating agent”) include, for example, acid generating agents disclosed in paragraphs [0077] to [0081] of Japanese Unexamined Patent Application, Publication No. 2004-168748.

In addition, examples of the acid generating agent that is capable of generating an acid upon heating (hereinafter, may be also referred to as “heat acid generating agent”) include onium salt-type acid generating agents exemplified as photo acid generating agents in the aforementioned Patent Document, as well as 2,4,4,6-tetrabromocyclohexadienone, benzoin tosylate, 2-nitrobenzyl tosylate, alkyl sulfonates and the like.

In a case in which the silicon-containing film-forming composition contains the acid generating agent, the upper limit of the content of the acid generating agent with respect to 100 parts by mass of the compound (A) is preferably 20 parts by mass, and more preferably 10 parts by mass.

In a case in which the silicon-containing film-forming composition contains the surfactant, colloidal silica, colloidal alumina and/or the organic polymer, the upper limit of the content of each type of these components with respect to 100 parts by mass of the compound (A) is preferably 2 parts by mass, and more preferably 1 part by mass.

Preparation Method of Silicon-Containing Film-Forming Composition A preparation method of the silicon-containing film-forming composition is not particularly limited, and the silicon-containing film-forming composition may be prepared by, for example, mixing at a predetermined ratio, a solution of the compound (A), the solvent (B), and optional component(s) that is/are to be contained as needed, and preferably filtering the resulting mixture through a filter having a pore size of 0.2 μm.

The lower limit of the solid content concentration of the silicon-containing film-forming composition is preferably 0.01% by mass, more preferably 0.05% by mass, and still more preferably 0.1% by mass. Meanwhile, the upper limit of the solid content concentration is preferably 30% by mass, more preferably 20% by mass, and still more preferably 10% by mass.

The solid content concentration of the silicon-containing film-forming composition as referred to herein means a value (% by mass) determined by: baking the silicon-containing film-forming composition at 250° C. for 30 min; measuring the mass of the solid content in the silicon-containing film-forming composition; and dividing the mass of this solid content by the mass of the silicon-containing film-forming composition.

Resist Film-Forming Composition-Applying Step

In this step, a resist film-forming composition is applied directly or indirectly on an upper face side of the silicon-containing film formed by applying the silicon-containing film-forming composition. This step allows the resist film to be formed on the upper face side of the silicon-containing film forming by applying the silicon-containing film-forming composition.

The resist composition is exemplified by a radiation-sensitive resin composition containing a polymer having an acid-labile group and a radiation-sensitive acid generating agent (a chemically amplified resist composition), a positive tone resist composition containing an alkali-soluble resin and a quinone diazide-based photosensitizing agent, a negative tone resist composition containing an alkali-soluble resin and a crosslinking agent, and the like. Of these, the radiation-sensitive resin composition is preferred. In a case where the radiation-sensitive resin composition is used, formation of a positive tone pattern is enabled by developing with an alkaline developer solution, whereas formation of a negative tone pattern is enabled by developing with an organic solvent developer solution. For forming the resist pattern, a procedure for fine pattern formation such as double patterning, double exposure or the like may be appropriately employed.

The polymer contained in the radiation-sensitive resin composition may have, in addition to a structural unit that includes the acid-labile group, for example, a structural unit that includes a lactone structure, a cyclic carbonate structure and/or a sultone structure; a structural unit that includes an alcoholic hydroxyl group; a structural unit that includes a phenolic hydroxyl group; a structural unit that includes a fluorine atom, etc. When the polymer has the structural unit that includes a phenolic hydroxyl group, and/or the structural unit that includes a fluorine atom, an improvement in sensitivity is enabled in the case of using an extreme ultraviolet ray or an electron beam as the radioactive ray in the exposure.

The lower limit of the solid content concentration of the resist composition is preferably 0.1% by mass, and more preferably 1% by mass. The upper limit of the solid content concentration is preferably 50% by mass, and more preferably 30% by mass. A resist composition filtered through a filter having a pore size of about 0.2 μm may be suitably used. In the pattern-forming method, a commercially available resist composition may be directly used as the resist composition.

A procedure for applying the resist composition may be exemplified by a conventional method such as, e.g., spin coating. In applying the resist composition, the amount of the resist composition to be applied is adjusted such that the resist film obtained has a predetermined film thickness.

The resist film may be formed by prebaking the coating film of the resist composition to allow the solvent in the coating film to be volatilized. The prebaking temperature may be appropriately adjusted depending on the type, etc., of the resist composition used; however, the lower limit of the prebaking temperature is preferably 30° C., and more preferably 50° C., whereas the upper limit of the prebaking temperature is preferably 200° C., and more preferably 150° C.

Exposing Step

In this step, the resist film formed by the resist film-forming composition-applying step is exposed to an extreme ultraviolet ray or an electron beam. The exposure to the extreme ultraviolet ray may be carried out by, for example, selectively irradiating with an extreme ultraviolet ray through a mask.

Developing Step

In this step, the resist film exposed is developed. This step allows a resist pattern to be formed on the upper face side of the silicon-containing film formed by the silicon-containing film-forming composition-applying step. In regard to the procedure for the development, either a development procedure with an alkali in which an alkaline developer solution is used, or a development procedure with an organic solvent in which an organic solvent developer solution is used may be employed. According to this step, development is carried out with a developer solution selected from various types and preferably followed by washing and drying, whereby a predetermined resist pattern corresponding to the photomask used in the exposing step is formed.

Silicon-Containing Film-Etching Step

According to this step, after the developing step, the silicon-containing film is etched by using, as a mask, the resist pattern formed by the developing step. More specifically, etching once or a plurality of times by using, as a mask, the resist pattern formed by the developing step executes patterning of the silicon-containing film formed by the silicon-containing film-forming composition-applying step.

The etching may be either dry etching or wet etching, and dry etching is preferred.

The dry etching may be carried out by using, for example, a known dry etching apparatus. An etching gas used for the dry etching may be appropriately selected depending on the element composition and the like of the silicon-containing film to be etched. Examples of the etching gas which may be used include: fluorine-based gasses such as CHF₃, CF₄, C₂F₆, C₃F₈ and SF₆; chlorine-based gasses such as Cl₂ and BCl₃; oxygen-based gasses such as O₂, O₃ and H₂O; reductive gasses such as H₂, NH₃, CO, CH₄, C₂H₂, C₂H₄, C₂H₆, C₃H₄, C₃H₆, C₃H₈, HF, HI, HBr, HCl, NO, NH₃ and BCl₃; inert gasses such as He, N₂ and Ar; and the like. These gasses may be used as a mixture. In dry etching of the silicon-containing film, a fluorine-based gas is typically used, and a mixture obtained by adding an oxygen-based gas and an inert gas to the fluorine-based gas may be suitably used.

Substrate-Etching Step

In this step, by using the patterned silicon-containing film as a mask, the substrate is etched. More specifically, a patterned substrate is obtained by etching once or a plurality of times, using as a mask the pattern formed on the silicon-containing film obtained by the silicon-containing film etching step.

In the case in which the organic underlayer film is formed on the substrate, a step of etching the organic underlayer film after the silicon-containing film-etching step is included, in which the silicon-containing film etched is used as a mask. A pattern is formed on the substrate by etching the substrate using, as a mask, the organic underlayer film pattern formed by the organic underlayer film-etching step.

The etching may be either dry etching or wet etching, and dry etching is preferred. The dry etching executed when forming the pattern on the organic underlayer film may be carried out by using, for example, a known dry etching apparatus. An etching gas used for the dry etching may be appropriately selected depending on the element composition and the like of the silicon-containing film and organic underlayer film to be etched. Examples of the etching gas which may be used include: fluorine-based gasses such as CHF₃, CF₄, C₂F₆, C₃F₈ and SF₆; chlorine-based gasses such as Cl₂ and BCl₃; oxygen-based gasses such as O₂, O₃ and H₂O; reductive gasses such as H₂, NH₃, CO, CH₄, C₂H₂, C₂H₄, C₂H₆, C₃H₄, C₃H₆, C₃H₈, HF, HI, HBr, HCl, NO, NH₃ and BCl₃; inert gasses such as He, N₂ and Ar; and the like. These gasses may be used as a mixture. In the dry etching of an organic underlayer film with the silicon-containing film pattern as a mask, an oxygen-based gas is typically used.

The dry etching executed when conducting the etching of the substrate with the organic underlayer film pattern as the mask may be carried out by using, for example, a known dry etching apparatus. An etching gas used for the dry etching may be appropriately selected depending on the element composition and the like of the organic underlayer film and the substrate to be etched. For example, etching gasses similar to those exemplified as the etching gasses which may be used in the dry etching of the organic underlayer film may be exemplified. The etching may be carried out a plurality of times, with different etching gasses.

Silicon-Containing Film-Removing Step

In this step, the silicon-containing film formed by the silicon-containing film-forming composition-applying step is removed. In a case in which the step is carried out after the substrate-etching step, the silicon-containing film remaining on at least the upper face of the substrate is removed. Also, this step may be performed on the etched silicon-containing film or the unetched silicon-containing film before the substrate-etching step.

The removing procedure of the silicon-containing film is exemplified by a dry etching procedure of the silicon-containing film, and the like. The dry etching may be conducted by using a known dry etching apparatus. Furthermore, examples of the source gas for use in the dry etching include: fluorine-based gasses such as CHF₃, CF₄, C₂F₆, C₃F₈ and SF₆; and chlorine-based gasses such as Cl₂ and BCl₃, and these gasses may be used as a mixture.

### EXAMPLES

Examples of the present invention will be demonstrated herein below. It should be noted that the following Examples merely illustrate one typical example of the present invention, and the scope of the present invention should not be construed to be narrowed by the Examples.

In the present Examples, measurements of: weight average molecular weight (Mw); the solid content concentration of the solution of the compound (A); and the average thickness of the film were conducted according to the following methods.

Weight Average Molecular Weight (Mw)

Measurements were carried out by gel permeation chromatography (detector: differential refractometer) by using GPC columns (“G2000HXL”×2, “G3000HXL”×1, “G4000HXL”×1, available from Tosoh Corporation) under an analytical condition involving: a flow rate of 1.0 mL/min; an elution solvent of tetrahydrofuran; and a column temperature of 40° C., with mono-dispersed polystyrene as a standard.

Solid Content Concentration of Solution of Compound (A)

A solution of the compound (A) in an amount of 0.5 g was baked at 250° C. for 30 min and the mass of a residue thus obtained (solid content) was measured, whereby the concentration (% by mass) of the solid content in the solution of the compound (A) was calculated.

Average Thickness of Silicon-Containing Film

The average thickness of the silicon-containing film was measured by using a spectroscopic ellipsometer (“M2000D”, available from J.A. Woollam Co., Inc.).

Synthesis of Compound (A)

Monomers used for syntheses in the Examples are presented below. It is to be noted that in the following Synthesis Examples, unless otherwise specified in particular, the term “parts by mass” means a value, provided that the total mass of the monomers used was 100 parts by mass.

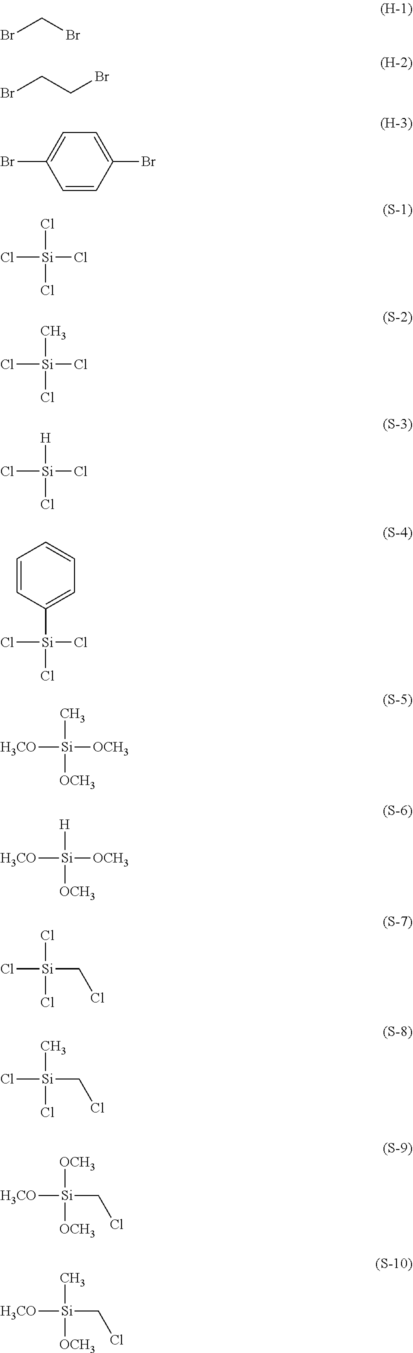

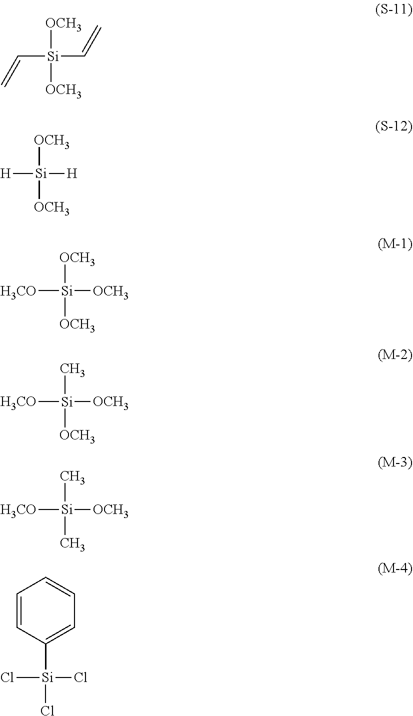

The expression “parts by mass” in the following Synthesis Examples 13 to 29 means a value, provided that the amount of a solution of polycarbosilane in diisopropyl ether used is 100 parts by mass, whereas “mol %” means a value, provided that the total number of moles of Si in the polycarbosilane and the monomer used is 100 mol %.

### Synthesis Example 1: Synthesis of Polycarbosilane (a-1)

In a reaction vessel filled with nitrogen, magnesium (120 mol %) and tetrahydrofuran (35 parts by mass) were charged, and the mixture was stirred at 20° C. Next, a compound represented by the above formula (H-1), a compound represented by the above formula (S-2) and a compound represented by the above formula (S-3) were dissolved in tetrahydrofuran (355 parts by mass) such that the molar ratio by percent was 50/15/35 (mol %) to prepare a monomer solution. The internal temperature of the reaction vessel was adjusted to 20° C., and the monomer solution was added dropwise thereto over 1 hour with stirring. A time point of completion of the dropwise addition was defined as a start time of the reaction, and the reaction was allowed at 40° C. for 1 hour, and then at 60° C. for 3 hrs. After completion of the reaction, tetrahydrofuran (213 parts by mass) was added to the polymerization solution, which was ice-cooled to no greater than 10° C. After triethylamine (150 mol %) was added to the polymerization solution thus cooled, methanol (150 mol %) was added dropwise from a dropping funnel over 10 min with stirring. A time point of completion of the dropwise addition was defined as a start time of the reaction, and the reaction was allowed at 20° C. for 1 hour. The polymerization solution was charged into diisopropyl ether (700 parts by mass), and a salt thus precipitated was filtered out. Next, tetrahydrofuran, excess triethylamine and excess methanol in the filtrate were removed by using an evaporator. A thus resulting residue was charged into diisopropyl ether (180 parts by mass), and a salt thus precipitated was filtered out. An addition of diisopropyl ether to the filtrate gave a solution of polycarbosilane (a-1) in diisopropyl ether having a solid content concentration of 10% by mass. The Mw of the polycarbosilane (a-1) was 700.

### Synthesis Examples 2 to 6 and Synthesis Examples 8 to 11: Syntheses of Polycarbosilanes (a-2) to (a-6) and (a-8) to (a-11)

Similarly to Synthesis Example 1 except that each monomer of the type and in the amount shown in Table 1 below was used, diisopropyl ether solutions of polycarbosilanes (a-2) to (a-6) and (a-8) to (a-11) were obtained. The Mw and the solid content concentration (% by mass) of the carbosilane in the solution of the polycarbosilane thus obtained are shown together in Table 1. In Table 1, “-” denotes that a corresponding monomer was not used.

### Synthesis Example 7: Synthesis of Polycarbosilane (a-7)

In a reaction vessel filled with nitrogen, magnesium (120 mol %), lithium chloride (11 mol %) and tetrahydrofuran (35 parts by mass) were charged, and the mixture was stirred at 20° C. Next, a compound represented by the above formula (H-1), a compound represented by the above formula (S-1), a compound represented by the formula (S-2), and a compound represented by the above formula (S-3) were dissolved in tetrahydrofuran (351 parts by mass) such that the molar ratio by percent was 50/5/15/30 (mol %) to prepare a monomer solution. The internal temperature of the reaction vessel was adjusted to 20° C., and the monomer solution was added dropwise thereto over 1 hour with stirring. A time point of completion of the dropwise addition was defined as a start time of the reaction, and the reaction was allowed at 40° C. for 1 hour, and then at 60° C. for 3 hrs. After completion of the reaction, tetrahydrofuran (210 parts by mass) was added to the polymerization solution, which was ice-cooled to no greater than 10° C. After triethylamine (150 mol %) was added to the polymerization solution thus cooled, methanol (150 mol %) was added dropwise from a dropping funnel over 10 min, with stirring. A time point of completion of the dropwise addition was defined as a start time of the reaction, and the reaction was allowed at 20° C. for 1 hour. The polymerization solution was charged into diisopropyl ether (700 parts by mass), and a salt thus precipitated was filtered out. Next, tetrahydrofuran, excess triethylamine and excess methanol in the filtrate were removed by using an evaporator. A thus resulting residue was charged into diisopropyl ether (180 parts by mass), and a salt thus precipitated was filtered out. An addition of diisopropyl ether to the filtrate gave a solution of polycarbosilane (a-7) in diisopropyl ether having a solid content concentration of 10% by mass. The Mw of the polycarbosilane (a-7) was 1,100.

### Synthesis Example 12: Synthesis of Polycarbosilane (a-12)

In a reaction vessel filled with nitrogen, a compound represented by the above formula (S-11) (52 mol %), tetrahydrofuran (200 parts by mass) and chloroplatinic acid (0.01 mol %) were charged, and the mixture was stirred at 40° C. Next, a compound represented by the above formula (S-12) (48 mol %) was dissolved in tetrahydrofuran (200 parts by mass) to prepare a solution for dropwise addition. The internal temperature of the reaction vessel was adjusted to 40° C., and the solution for dropwise addition was added dropwise thereto over 1 hour with stirring. A time point of completion of the dropwise addition was defined as a start time of the reaction, and the reaction was allowed at 60° C. for 3 hrs. After completion of the reaction, the polymerization solution was water-cooled to no greater than 30° C. After the cooling, tetrahydrofuran in the polymerization solution was removed by using an evaporator. A thus resulting residue was dissolved in diisopropyl ether to give a solution of polycarbosilane (a-12) in diisopropyl ether having a solid content concentration of 10% by mass. The Mw of the polycarbosilane (a-12) was 2,100.

TABLE 1

| | | | | | | | | | | | | | | | | | Solid content | |
|---|---|---|---|---|---|---|---|---|---|---|---|---|---|---|---|---|---|---|
| | | Amount of each monomer charged (mol %) | | | | | | | | | | | | | | | concentration | |
| | Polycarbosilane | H-1 | H-2 | H-3 | S-1 | S-2 | S-3 | S-4 | S-5 | S-6 | S-7 | S-8 | S-9 | S-10 | S-11 | S-12 | (% by mass) | Mw |
| Synthesis | a-1 | 50 | — | — | — | 15 | 35 | — | — | — | — | — | — | — | — | — | 10 | 700 |
| Example 1 | | | | | | | | | | | | | | | | | | |
| Synthesis | a-2 | 50 | — | — | 5 | 15 | 30 | — | — | — | — | — | — | — | — | — | 10 | 800 |
| Example 2 | | | | | | | | | | | | | | | | | | |
| Synthesis | a-3 | 40 | — | 5 | 10 | 15 | 30 | — | — | — | — | — | — | — | — | — | 10 | 700 |
| Example 3 | | | | | | | | | | | | | | | | | | |
| Synthesis | a-4 | — | 55 | — | 5 | — | 40 | — | — | — | — | — | — | — | — | — | 10 | 900 |
| Example 4 | | | | | | | | | | | | | | | | | | |
| Synthesis | a-5 | — | — | 50 | 20 | — | 30 | — | — | — | — | — | — | — | — | — | 10 | 800 |
| Example 5 | | | | | | | | | | | | | | | | | | |
| Synthesis | a-6 | 55 | — | — | 10 | — | 30 | 5 | — | — | — | — | — | — | — | — | 10 | 700 |
| Example 6 | | | | | | | | | | | | | | | | | | |
| Synthesis | a-7 | 50 | — | — | 5 | 15 | 30 | — | — | — | — | — | — | — | — | — | 10 | 1,100 |
| Example 7 | | | | | | | | | | | | | | | | | | |
| Synthesis | a-8 | 50 | — | — | — | — | — | — | 10 | 40 | — | — | — | — | — | — | 10 | 600 |
| Example 8 | | | | | | | | | | | | | | | | | | |
| Synthesis | a-9 | — | — | — | — | — | — | — | — | — | 50 | 50 | — | — | — | — | 10 | 1,200 |
| Example 9 | | | | | | | | | | | | | | | | | | |
| Synthesis | a-10 | — | 40 | — | — | — | 30 | — | — | — | — | 30 | — | — | — | — | 10 | 900 |
| Example 10 | | | | | | | | | | | | | | | | | | |
| Synthesis | a-11 | — | — | — | — | — | — | — | — | — | — | — | 65 | 35 | — | — | 10 | 600 |
| Example 11 | | | | | | | | | | | | | | | | | | |
| Synthesis | a-12 | — | — | — | — | — | — | — | — | — | — | — | — | — | 52 | 48 | 10 | 2,100 |
| Example 12 | | | | | | | | | | | | | | | | | | |

### (A) Compound

### Synthesis Example 13: Synthesis of (A) Compound (A-1)

In a reaction vessel, a solution of the polycarbosilane (A-1) in diisopropyl ether was dissolved in 90 parts by mass of methanol. The internal temperature of the reaction vessel was adjusted to 30° C., and 8 parts by mass of a 3.2% by mass aqueous oxalic acid solution were added dropwise thereto over 20 min with stirring. A time point of completion of the dropwise addition was defined as a start time of the reaction, and the reaction was allowed at 40° C. for 4 hrs. After completion of the reaction, the internal temperature of the reaction vessel was cooled to no greater than 30° C. To the cooled reaction solution were added 198 parts by mass of propylene glycol monomethyl ether acetate, and then alcohols produced by the reaction, excess propylene glycol monomethyl ether acetate and water were removed by using an evaporator to give a solution of the (A) compound (A-1) in propylene glycol monomethyl ether acetate. The Mw of the (A) compound (A-1) was 2,500. The solid content concentration of the solution of the (A) compound (A-1) in propylene glycol monomethyl ether acetate was 5% by mass.

### Synthesis Examples 15, 21, 23 and 25: Syntheses of (A) Compounds (A-3), (A-9), (A-11) and (A-13)

Similarly to Synthesis Example 13 except that each monomer of the type and in the amount shown in Table 1 below was used, solutions of (A) compounds (A-3), (A-9), (A-11) and (A-13) in propylene glycol monomethyl ether acetate were obtained. The Mw and the solid content concentration (% by mass) of the compound (A) in the solution of the compound (A) thus obtained are shown together in Table 2. It is to be noted that “-” for the monomer in Table 2 below denotes that a corresponding component was not used.

### Synthesis Example 14: Synthesis of (A) Compound (A-2)

In a reaction vessel, a solution of the polycarbosilane (A-1) in diisopropyl ether (80 mol %) and a compound represented by the above formula (M-2) (20 mol %) were dissolved in methanol (139 parts by mass). The internal temperature of the reaction vessel was adjusted to 30° C., and 14 parts by mass of a 3.2% by mass aqueous oxalic acid solution were added dropwise thereto over 20 min with stirring. A time point of completion of the dropwise addition was defined as a start time of the reaction, and the reaction was allowed at 40° C. for 4 hrs. After completion of the reaction, the internal temperature of the reaction vessel was cooled to no greater than 30° C. To the cooled reaction solution were added 259 parts by mass of propylene glycol monomethyl ether acetate, and then alcohols produced by the reaction, excess propylene glycol monomethyl ether acetate and water were removed by using an evaporator to give a solution of the (A) compound (A-2) in propylene glycol monomethyl ether acetate. The Mw of the (A) compound (A-2) was 1,800. The solid content concentration of the solution of the (A) compound (A-2) in propylene glycol monomethyl ether acetate was 5% by mass.

### Synthesis Examples 16, 17, 19, 20, 22, 24 and 26 to 29: Syntheses of (A) Compounds (A-4), (A-5), (A-7), (A-8), (A-10), (A-12) and (A-14) to (A-17)

Similarly to Synthesis Example 14 except that each monomer of the type and in the amount shown in Table 2 below was used, solutions of (A) compounds (A-4), (A-5), (A-7), (A-8), (A-10), (A-12) and (A-14) to (A-17) in propylene glycol monomethyl ether acetate were obtained. The Mw and the solid content concentration (% by mass) of the compound (A) in the solution of the compound (A) thus obtained are shown together in Table 2.

### Synthesis Example 18: Synthesis of (A) Compound (A-6)

In a reaction vessel, tetramethylammonium hydroxide (TMAH) (80 mol %) was dissolved in water (35 parts by mass). Next, polycarbosilane (a-3) (80 mol %) and a compound represented by the above formula (M-2) (20 mol %) were dissolved in methanol (123 parts by mass) to prepare a solution for dropwise addition. The internal temperature of the reaction vessel was adjusted to 40° C., and the solution for dropwise addition was added dropwise over 1 hour with stirring. A time point of completion of the dropwise addition was defined as a start time of the reaction, and the reaction was allowed at 60° C. for 3 hrs. After completion of the reaction, the polymerization solution was water-cooled to no greater than 30° C.

An aqueous maleic acid solution was separately prepared by dissolving maleic anhydride (96 mol %) in water (309 parts by mass), and n-butanol (254 parts by mass) was added thereto, followed by cooling to no greater than 10° C. Subsequently, the polymerization solution was added dropwise to this maleic acid solution over 60 min with stirring. After completion of the dropwise addition, the polymerization solution was transferred to a separatory funnel, and the water layer was removed. Water (254 parts by mass) was added to the mixture, and then washing with water was conducted twice. The reaction solution was transferred to a flask after the washing with water, and propylene glycol monomethyl ether acetate (254 parts by mass) was added to this flask. Thereafter, water and n-butanol were removed by using an evaporator to give a solution of the (A) compound (A-6) in propylene glycol monomethyl ether acetate. The Mw of the (A) compound (A-6) was 3,400. The solid content concentration of the solution of the (A) compound (A-6) in propylene glycol monomethyl ether acetate was 5% by mass.

### Synthesis Example 30: Synthesis of (A) Compound (A-18)

In a reaction vessel, a compound represented by the above formula (M-1), a compound represented by the above formula (M-2), and a compound represented by the above formula (M-4) were dissolved in methanol (134 parts by mass) such that the molar ratio by percent was 65/25/10 (mol %) to prepare a monomer solution. The internal temperature of the reaction vessel was adjusted to 60° C., and 47 parts by mass of a 9.1% by mass aqueous oxalic acid solution were added dropwise thereto over 20 min with stirring. A time point of completion of the dropwise addition was defined as a start time of the reaction, and the reaction was allowed for 4 hrs. After completion of the reaction, the internal temperature of the reaction vessel was cooled to no greater than 30° C. To the cooled reaction solution was added propylene glycol monomethyl ether acetate (519 parts by mass), and then alcohols produced by the reaction, excess propylene glycol monomethyl ether acetate and water were removed by using an evaporator to give a solution of the (A) compound (A-18) in propylene glycol monomethyl ether acetate. The Mw of the (A) compound (A-18) was 1,900. The solid content concentration of the solution of the (A) compound (A-18) in propylene glycol monomethyl ether acetate was 5% by mass.

### Synthesis Example 31: Synthesis of (A) Compound (A-19)

In a reaction vessel, tetramethylammonium hydroxide (60 mol %) was dissolved in water (113 parts by mass). Next, a compound represented by the above formula (M-1) and a compound represented by the above formula (M-2) were dissolved in n-butanol (38 parts by mass) such that the molar ratio by percent was 60/40 (mol %) to prepare a monomer solution. The internal temperature of the reaction vessel was adjusted to 40° C., and the solution for dropwise addition was added dropwise over 1 hour with stirring. A time point of completion of the dropwise addition was defined as a start time of the reaction, and the reaction was allowed at 60° C. for 3 hrs. After completion of the reaction, the polymerization solution was water-cooled to no greater than 30° C.

An aqueous maleic acid solution was separately prepared by dissolving maleic anhydride (72 mol %) in water (692 parts by mass), and n-butanol (514 parts by mass) was added thereto, followed by cooling to no greater than 10° C. Subsequently, the polymerization solution was added dropwise to this maleic acid solution over 60 min with stirring. After completion of the dropwise addition, the polymerization solution was transferred to a separatory funnel, and the water layer was removed. Water (514 parts by mass) was added to the mixture, and then washing with water was conducted twice. The reaction solution was transferred to a flask after the washing with water, and propylene glycol monomethyl ether acetate (514 parts by mass) was added to this flask. Thereafter, water and n-butanol were removed by using an evaporator to give a solution of the (A) compound (A-19) in propylene glycol monomethyl ether acetate. The Mw of the (A) compound (A-19) was 1,500. The solid content concentration of the solution of the (A) compound (A-19) in propylene glycol monomethyl ether acetate was 5% by mass.

TABLE 2

| | | Amount of | | | | | | Solid content | |
|---|---|---|---|---|---|---|---|---|---|
| | (A) | each monomer charged (Si mol %) | | | | | | concentration | |
| | Compound | polycarbosilane | | M-1 | M-2 | M-3 | M-4 | (% by mass) | Mw |
| Synthesis | A-1 | a-1 | 100 | — | — | — | — | 5 | 2,500 |
| Example 13 | | | | | | | | | |
| Synthesis | A-2 | a-1 | 80 | — | 20 | — | — | 5 | 1,800 |
| Example 14 | | | | | | | | | |
| Synthesis | A-3 | a-2 | 100 | — | — | — | — | 5 | 2,100 |
| Example 15 | | | | | | | | | |
| Synthesis | A-4 | a-2 | 80 | — | 10 | — | 10 | 5 | 1,300 |
| Example 16 | | | | | | | | | |
| Synthesis | A-5 | a-3 | 90 | 10 | — | — | — | 5 | 1,800 |
| Example 17 | | | | | | | | | |
| Synthesis | A-6 | a-3 | 80 | — | 20 | — | — | 5 | 3,400 |
| Example 18 | | | | | | | | | |
| Synthesis | A-7 | a-4 | 80 | 15 | 5 | — | — | 5 | 2,300 |
| Example 19 | | | | | | | | | |
| Synthesis | A-8 | a-5 | 50 | 45 | — | — | 5 | 5 | 1,900 |
| Example 20 | | | | | | | | | |
| Synthesis | A-9 | a-6 | 100 | — | — | — | — | 5 | 2,200 |
| Example 21 | | | | | | | | | |
| Synthesis | A-10 | a-7 | 80 | — | 20 | — | — | 5 | 2,600 |
| Example 22 | | | | | | | | | |
| Synthesis | A-11 | a-7 | 100 | — | — | — | — | 5 | 1,700 |
| Example 23 | | | | | | | | | |
| Synthesis | A-12 | a-8 | 65 | — | 25 | 10 | — | 5 | 1,800 |
| Example 24 | | | | | | | | | |
| Synthesis | A-13 | a-9 | 100 | — | — | — | — | 5 | 2,400 |
| Example 25 | | | | | | | | | |
| Synthesis | A-14 | a-9 | 70 | 20 | 10 | — | — | 5 | 2,500 |
| Example 26 | | | | | | | | | |
| Synthesis | A-15 | a-10 | 75 | 20 | — | — | 5 | 5 | 1,800 |
| Example 27 | | | | | | | | | |
| Synthesis | A-16 | a-11 | 30 | 40 | 20 | 10 | — | 5 | 1,400 |
| Example 28 | | | | | | | | | |
| Synthesis | A-17 | a-12 | 50 | — | 30 | 20 | — | 5 | 2,000 |
| Example 29 | | | | | | | | | |
| Synthesis | A-18 | — | — | 65 | 25 | — | 10 | 5 | 1,900 |
| Example 30 | | | | | | | | | |
| Synthesis | A-19 | — | — | 60 | 40 | — | — | 5 | 1,500 |
| Example 31 | | | | | | | | | |

### (B) Solvent

B-1: propylene glycol monomethyl ether acetate

### (C) Additives

C-1 (Acid generating agent): a compound represented by the following formula (C-1)

C-2 (Basic compound): a compound represented by the following formula (C-2)

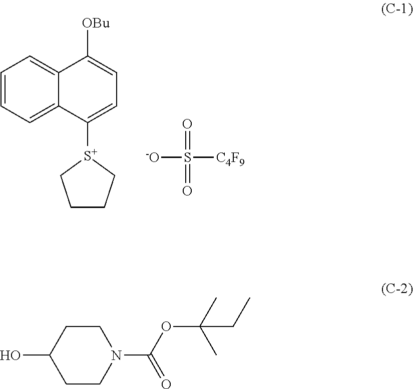

### Example 1

A silicon-containing film-forming composition (J-1) was prepared by: mixing 0.5 parts by mass of (A-1) as the compound (A) (solid content), 99.49 parts by mass of (B-1) as the solvent (B) (including also (B-1) as the solvent contained in the solution of the compound (A)) and 0.01 parts by mass of (C-1) as the additive (C); and then filtering a resultant solution through a filter having a pore size of 0.2 μm.

### Examples 2 to 18 and Comparative Examples 1 to 2

Silicon-containing film-forming compositions (J-1) to (J-18) of Examples 2 to 18, and silicon-containing film-forming compositions (j-1) to (j-2) of Comparative Examples 1 to 2 were prepared in a similar manner to Example 1 except that the type and the content of each component were as presented in Table 3 below. In the following Table 3, “-” denotes that a corresponding component was not used.

### Evaluations

Each silicon-containing film-forming composition was evaluated on its resist pattern collapse-inhibiting property, resistance to etching by oxygen-based gas and solvent resistance according to the following methods. The results of the evaluations are shown in Table 3 below.

Resist Pattern Collapse-Inhibiting Property: Resist Pattern Collapse-Inhibiting Property Upon Exposure to Electron Beam or Exposure to Extreme Ultraviolet Ray

An antireflective film having an average thickness of 100 nm was formed on an 8-inch silicon wafer by applying a material for forming an antireflective film (“HM8006” available from JSR Corporation) by spin coating with the spin coater, and then heating at 250° C. for 60 sec. A silicon-containing film having an average thickness of 13 nm was formed by applying the composition for silicon-containing film formation onto the antireflective film and heating at 220° C. for 60 sec, followed by cooling at 23° C. for 30 sec.

Subsequently, a resist film having an average thickness of 50 nm was formed by applying a radiation-sensitive resin composition described later onto the silicon-containing film thus formed, and heating at 130° C. for 60 sec, followed by cooling at 23° C. for 30 sec.

The radiation-sensitive resin composition was obtained by mixing: 100 parts by mass of a polymer having a structural unit (1) derived from 4-hydroxystyrene, a structural unit (2) derived from styrene and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; and as solvents, 1,500 parts by mass of ethyl lactate and 700 parts by mass of propylene glycol monomethyl ether acetate, and filtering the resulting solution through a filter having a pore size of 0.2 μm.

In the case of the exposure to an electron beam, the resist film was irradiated with the electron beam by using an electron beam writer (“HL800D” available from Hitachi, Ltd., output: 50 KeV, electric current density: 5.0 ampere/cm²). After the irradiation with the electron beam, the substrate was heated at 110° C. for 60 sec, and then cooled at 23° C. for 60 sec. Thereafter, a 2.38% by mass aqueous TMAH solution (20 to 25° C.) was used to carry out a development according to a puddle procedure. Subsequently, washing with water, followed by drying, gave a resist-patterned substrate for evaluation. In the resist pattern formation, an exposure dose at which a 1:1 line-and-space pattern was formed with a line width of 150 nm was defined as an “optimal exposure dose”.

For a line-width measurement and inspection of the resist pattern of the substrate for evaluation, a scanning electron microscope (“CG-4000” available from Hitachi High-Technologies Corporation) was employed. The collapse-inhibiting property was evaluated, at the optimum exposure dose, as: “A” (favorable) when pattern collapse was not found; and “B” (unfavorable) when pattern collapse was found.

In the case of the exposure to an extreme ultraviolet ray, the resist film was exposed by using an EUV scanner (“TWINSCAN NXE: 3300B” available from ASML (NA: 0.3, Sigma: 0.9, quadle pole illumination, mask of a 1:1 line-and-space pattern with a line width of 25 nm in terms of dimension on the wafer)). After the exposure, the substrate was heated at 110° C. for 60 sec, and then cooled at 23° C. for 60 sec. Thereafter, a 2.38% by mass aqueous TMAH solution (20 to 25° C.) was used to carry out a development according to a puddle procedure. Subsequently, washing with water, followed by drying, gave a resist-patterned substrate for evaluation. In the resist pattern formation, an exposure dose at which a 1:1 line-and-space pattern was formed with a line width of 25 nm was defined as an “optimal exposure dose”. For a line-width measurement and inspection of the resist pattern of the substrate for evaluation, a scanning electron microscope (“CG-4000” available from Hitachi High-Technologies Corporation) was employed. The collapse-inhibiting property was evaluated, at the optimum exposure dose, as: “A” (favorable) when pattern collapse was not observed; and “B” (unfavorable) when pattern collapse was observed.

Solvent Resistance

A silicon-containing film having an average thickness of 20 nm was formed on an 8-inch silicon wafer by applying the silicon-containing film-forming composition and heating at 220° C. for 60 sec, followed by cooling at 23° C. for 30 sec.

The substrate on which the silicon-containing film was formed was immersed in cyclohexanone (20 to 25° C.) for 10 sec and then dried. Average thicknesses of the silicon-containing film prior to and subsequent to the immersion were measured. The rate of change in film thickness (%) was determined according to the following formula, provided that the average thickness of the silicon-containing film prior to the immersion was T₀, and the average thickness of the silicon-containing film subsequent to the immersion T₁. The solvent resistance was evaluated to be: “A” (favorable) in the case of the rate of change in film thickness being less than 1%; and “B” (unfavorable) in the case of the rate of change in film thickness being no less than 1%.

rate of change in film thickness (%)=|T₁−T₀|×100/T₀

Resistance to Etching by Oxygen-Based Gas

A silicon-containing film having an average thickness of 20 nm was formed on an 8-inch silicon wafer by applying the silicon-containing film-forming composition and heating at 220° C. for 60 sec, followed by cooling at 23° C. for 30 sec.

The substrate on which the silicon-containing film was formed was subjected to an etching treatment by using an etching apparatus (“Tactras-Vigus” available from Tokyo Electron Limited), under conditions involving O₂=400 sccm, PRESS.=25 mT, HF RF=200 W, LF RF=0 W, DCS=0 V, RDC=50%, for 60 sec. The etching rate (nm/min) was calculated from average film thicknesses prior to and subsequent to the treatment, whereby the resistance to etching by oxygen was evaluated. The resistance to etching by oxygen was evaluated to be: “A” (particularly favorable) in the case of the etching rate being less than 4.5 nm/min; “B” (favorable) in the case of the etching rate being no less than 4.5 nm/min and less than 5.0 nm/min; and “C” (unfavorable) in the case of the etching rate being no less than 5.0 nm/min.

TABLE 3

| | | | | | | | | Evaluation | | | |
|---|---|---|---|---|---|---|---|---|---|---|---|
| | | | | | | | | Resist pattern collapse-inhibiting | | | |
| | Silicon- | (A) Compound | | (B) Solvent | | (C) Additive | | property | | Resistance to | |
| | containing | | amount | | amount | | amount | | exposure to | etching by | |
| | film-forming | | (parts by | | (parts by | | (parts by | exposure to | extreme | oxygen-based | Solvent |
| | composition | type | mass) | type | mass) | type | mass) | electron beam | ultraviolet ray | gas | resistance |
| Example 1 | J-1 | A-1 | 0.5 | B-1 | 99.49 | C-1 | 0.01 | A | A | A | A |
| Example 2 | J-2 | A-1 | 0.5 | B-1 | 99.50 | — | — | A | A | A | A |
| Example 3 | J-3 | A-2 | 0.5 | B-1 | 99.50 | — | — | A | A | A | A |
| Example 4 | J-4 | A-3 | 0.5 | B-1 | 99.50 | — | — | A | A | A | A |
| Example 5 | J-5 | A-4 | 0.5 | B-1 | 99.50 | — | — | A | A | B | A |
| Example 6 | J-6 | A-5 | 0.5 | B-1 | 99.50 | — | — | A | A | A | A |
| Example 7 | J-7 | A-6 | 0.5 | B-1 | 99.50 | — | — | A | A | A | A |
| Example 8 | J-8 | A-7 | 0.5 | B-1 | 99.50 | — | — | A | A | B | A |
| Example 9 | J-9 | A-8 | 0.5 | B-1 | 99.50 | — | — | A | A | B | A |
| Example 10 | J-10 | A-9 | 0.5 | B-1 | 99.49 | C-2 | 0.01 | A | A | A | A |
| Example 11 | J-11 | A-10 | 0.5 | B-1 | 99.50 | — | — | A | A | A | A |
| Example 12 | J-12 | A-11 | 0.5 | B-1 | 99.50 | — | — | A | A | A | A |
| Example 13 | J-13 | A-12 | 0.5 | B-1 | 99.50 | — | — | A | A | A | A |
| Example 14 | J-14 | A-13 | 0.5 | B-1 | 99.50 | — | — | A | A | A | A |
| Example 15 | J-15 | A-14 | 0.5 | B-1 | 99.50 | — | — | A | A | A | A |
| Example 16 | J-16 | A-15 | 0.5 | B-1 | 99.50 | — | — | A | A | A | A |
| Example 17 | J-17 | A-16 | 0.5 | B-1 | 99.50 | — | — | A | A | B | A |
| Example 18 | J-18 | A-17 | 0.5 | B-1 | 99.50 | — | — | A | A | B | A |
| Comparative | j-1 | A-18 | 0.5 | B-1 | 99.50 | — | — | B | B | C | A |
| Example 1 | | | | | | | | | | | |
| Comparative | j-2 | A-19 | 0.5 | B-1 | 99.50 | — | — | A | A | C | A |
| Example 2 | | | | | | | | | | | |

As is clear from Table 3 above, the silicon-containing films formed from the silicon-containing film-forming compositions of the Examples were favorable in both the resistance to etching by oxygen-based gas and the solvent resistance. Also, in both the cases of the exposure to the electron beam and the exposure to the extreme ultraviolet ray, the resist pattern collapse-inhibiting property was favorable. To the contrary, the silicon-containing films formed from the silicon-containing film-forming compositions of the Comparative Examples were inferior in the etching resistance.

The silicon-containing film-forming compositions according to the embodiment of the present invention enable a silicon-containing film to be formed with a superior resist pattern collapse-inhibiting property and superior resistance to etching by oxygen-based gas and to solvents. Therefore, these can be suitably used for manufacture of semiconductor devices and the like in which microfabrication is expected to progress further hereafter.

Obviously, numerous modifications and variations of the present invention are possible in light of the above teachings. It is therefore to be understood that within the scope of the appended claims, the invention may be practiced otherwise than as specifically described herein.

What is claimed is:

1. A pattern-forming method comprising:
applying a silicon-containing film-forming composition directly or indirectly on at least an upper face side of a substrate to form a silicon-containing film;
applying a resist film-forming composition directly or indirectly on an upper face side of the silicon-containing film to form a resist film;
exposing the resist film to an extreme ultraviolet ray (EUV) or an electron beam; and
developing the resist film exposed to form a resist pattern,
wherein the silicon-containing film-forming composition comprises:
a compound comprising a first structural unit represented by formula (1); and
a solvent, 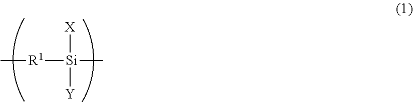
wherein, in the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.

2. The pattern-forming method according to claim 1, wherein the compound further comprises a second structural unit represented by formula (2):
(SiO_{4/2}) (2)

3. The pattern-forming method according to claim 1, wherein the compound further comprises a third structural unit represented by formula (3): 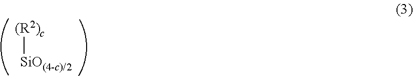
wherein, in the formula (3), R² represents a substituted or unsubstituted monovalent hydrocarbon group having 1 to 20 carbon atoms; and c is an integer of 1 or 2, wherein in a case in which c is 2, two R^{e}s are identical or different.

4. The pattern-forming method according to claim 1, further comprising
after the developing, etching the silicon-containing film using the resist pattern as a mask.

5. The pattern-forming method according to claim 4, further comprising:
before the applying of the silicon-containing film-forming composition, forming an organic underlayer film directly or indirectly on at least an upper face side of the substrate; and
after the etching of the silicon-containing film, etching the organic underlayer film using, as a mask, the silicon-containing film etched.

6. A silicon-containing film-forming composition comprising:
a compound comprising a structural unit represented by formula (1); and
a solvent, 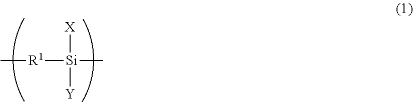
wherein, in the formula (1), R¹ represents a substituted or unsubstituted divalent hydrocarbon group having 1 to 20 carbon atoms; and X and Y each independently represent a hydrogen atom, a hydroxy group, a halogen atom or a monovalent organic group having 1 to 20 carbon atoms.
